(19) United States
(12) Patent Application Publication
(10) Pub. No.: US 2015/0266044 A1
(43) Pub. Date: Sep. 24, 2015

(54) SLOT DIE COATER AND COATING METHOD USING THE SAME

(71) Applicant: Samsung Display Co., Ltd., Yongin-City (KR)

(72) Inventors: Jae Cheol PARK, Hwaseong-si (KR); Yeun Tae KIM, Hwaseong-si (KR); Gyeong Eun EOH, Seoul (KR); Dae Ho SONG, Hwaseong-si (KR); Min Jeong OH, Incheon (KR); Jun Heui LEE, Seoul (KR)

(21) Appl. No.: 14/493,060

(22) Filed: Sep. 22, 2014

(30) Foreign Application Priority Data
Mar. 18, 2014 (KR) 10-2014-0031850

(51) Int. Cl. B05B 15/06; H01L 21/02; H01L 27/12; B05B 1/04

(52) U.S. Cl. CPC B05B 15/06; B05B 1/044; H01L 21/02282; H01L 21/02348; H01L 21/02359; H01L 27/1292; H01L 27/1214

(57) ABSTRACT

The present invention relates to a slot die coater preventing contamination of another layer contacting a coating layer, and a coating method using the same. The slot die coater according to an exemplary embodiment of the present invention includes a slit nozzle configured to deposit a photo-curable material upon a substrate, and an exposure unit coupled to the slit nozzle and positioned adjacent thereto, the exposure unit configured to irradiate light upon the photo-curable material deposited upon the substrate.

### CROSS-REFERENCE TO RELATED APPLICATION

This application claims priority to, and the benefit of, Korean Patent Application No. 10-2014-0031850 filed in the Korean Intellectual Property Office on Mar. 18, 2014, the entire contents of which are incorporated herein by reference.

### BACKGROUND

(a) Technical Field

Embodiments of the present invention relate generally to semiconductor fabrication. More particularly, embodiments of the present invention relate to a slot die coater and a coating method using the same.

(b) Description of the Related Art

Liquid crystal displays are now widely used as one type of flat panel display technology. A liquid crystal display has two display panels on which field generating electrodes such as pixel electrodes and a common electrode are formed, and a liquid crystal layer is interposed between the panels. Voltages are applied to the field generating electrodes so as to generate an electric field in the liquid crystal layer, and the alignment of liquid crystal molecules of the liquid crystal layer is determined by the electric field. Accordingly, the polarization of incident light is controlled, thereby performing image display.

The two display panels forming the liquid crystal display may be a thin film transistor array panel and an opposing display panel. In the thin film transistor array panel, a gate line transmitting a gate signal and a data line transmitting a data signal are formed to be crossed, and a thin film transistor connected to the gate line and the data line, as well as a pixel electrode connected to the thin film transistor, may be formed. The opposing display panel may include a light blocking member, a color filter, a common electrode, etc. If necessary, the light blocking member, the color filter, and the common electrode may be formed in the thin film transistor array panel.

Recently, an attempt to reduce cost by forming these constituent elements on one substrate has been researched. In this case, after forming the liquid crystal layer, a layer sealing the liquid crystal layer is required. However, the layer for sealing the liquid crystal layer contacts the liquid crystal material, such that there is a problem that the liquid crystal layer may be contaminated.

The above information disclosed in this Background section is only for enhancement of understanding of the background of the invention and therefore it may contain information that does not form the prior art that is already known in this country to a person of ordinary skill in the art.

### SUMMARY

The present invention provides a slot die coater preventing contamination of another layer contacting a coating layer, and a coating method using the same.

A slot die coater according to an exemplary embodiment of the present invention includes a slit nozzle configured to supply a photo-curable material, and an exposure unit coupled to the slit nozzle and positioned adjacent thereto, the exposure unit configured to irradiate light upon the photo-curable material deposited upon the substrate.

The exposure unit may be affixed to the slit nozzle.

The slot die coater according to an exemplary embodiment of the present invention may further include a gantry supporting the slit nozzle and the exposure unit.

The slot die coater according to an exemplary embodiment of the present invention may further include a stage located under positions of the slit nozzle and exposure unit at which the photo-curable material is respectively configured to be deposited and to be irradiated, and a rail upon which the gantry is mounted.

The rail may be coupled to two side surfaces of the stage, the two side surfaces facing each other.

The exposure unit may be affixed to the gantry.

The gantry may include a first gantry and a second gantry, the slit nozzle may be affixed to the first gantry, and the exposure unit may be affixed to the second gantry.

The exposure unit may include a light source unit configured to generate light, and a controller controlling supply of the generated light.

The light source unit may include one or more of a light emitting diode (LED) and a high pressure mercury lamp configured to generate ultraviolet rays.

The controller may include a controller configured to switch the light source unit on and off.

The exposure unit may further include a shutter configured to block light from the light source unit, and the controller may be configured to control the shutter so as to control a blocking of light from the light source unit.

The slot die coater may be further configured to deposit the photo-curable material upon the substrate and to irradiate the deposited photo-curable material so as to form a layer of a display device.

The display device may include: a substrate; a thin film transistor formed on the substrate; a pixel electrode connected to the thin film transistor; a roof layer formed on the pixel electrode so as to be spaced apart from the pixel electrode while interposing a plurality of microcavities therebetween; an injection hole exposing a portion of each microcavity; a liquid crystal layer positioned within the microcavity; and an encapsulation layer formed on the roof layer so as to cover the injection hole and to thereby seal the microcavity.

The slot die coater may be further configured to deposit the photo-curable material upon the substrate and to irradiate the deposited photo-curable material so as to form the encapsulation layer.

A coating method according to an exemplary embodiment of the present invention includes: mounting a substrate upon a stage; applying a photo-curable material to the substrate through a slit nozzle; irradiating light upon the substrate through an exposure unit positioned to be adjacent to the slit nozzle; stopping the applying of the photo-curable material; and after the stopping the applying, stopping the irradiating.

The exposure unit may harden the photo-curable material while being moved along with the slit nozzle.

The slit nozzle and the exposure unit may be affixed to the gantry, and the method may further comprise moving the gantry so as to move the slit nozzle together with the exposure unit.

The method may further include moving the slit nozzle and the exposure unit from one side edge of the substrate toward another side edge of the substrate during the applying and during the irradiating.

The substrate may have formed thereon a thin film transistor, a pixel electrode connected to the thin film transistor, a roof layer formed on the pixel electrode so as to be spaced apart from the pixel electrode while interposing a plurality of microcavities therebetween, an injection hole exposing a part of each microcavity, and a liquid crystal layer positioned within the microcavity.

The irradiating may further comprise irradiating light upon the applied photo-curable material so as to harden the photo-curable material, and so as to thereby form an encapsulation layer sealing the microcavity.

The slot die coater and the coating method using the same according to an exemplary embodiment of the present invention have effects as follows.

The slot die coater and the coating method using the same according to an exemplary embodiment of the present invention disposes the exposure unit to be adjacent to the slit nozzle, such that the hardening process is performed directly after coating the photo-curable material, thereby preventing the uncured photo-curable material from contaminating the liquid crystal.

### BRIEF DESCRIPTION OF THE DRAWINGS

FIG. 1 is a perspective view of a portion of a slot die coater according to an exemplary embodiment of the present invention.

FIG. 2 is a top plan view of a slot die coater according to an exemplary embodiment of the present invention.

FIG. 3 and FIG. 4 are block diagrams of an exposure unit of a slot die coater according to an exemplary embodiment of the present invention.

FIG. 5 is a top plan view of a slot die coater according to another exemplary embodiment of the present invention.

FIG. 6 is a top plan view showing a process of moving a slit nozzle of a slot die coater and an exposure unit according to an exemplary embodiment of the present invention.

FIG. 7 is a cross-sectional view showing a process of moving a slit nozzle of a slot die coater and an exposure unit according to an exemplary embodiment of the present invention.

FIG. 8 is a top plan view of a display device manufactured by using a slot die coater according to an exemplary embodiment of the present invention.

FIG. 9 is an equivalent circuit diagram of one pixel of a display device manufactured by using a slot die coater according to an exemplary embodiment of the present invention.

FIG. 10 is a layout view of a portion of a display device manufactured by using a slot die coater according to an exemplary embodiment of the present invention.

FIG. 11 is a cross-sectional view of a display device manufactured by using a slot die coater according to an exemplary embodiment of the present invention, as taken along a line XI-XI of FIG. 10.

FIG. 12 is a cross-sectional view of a display device manufactured by using a slot die coater according to an exemplary embodiment of the present invention, as taken along a line XII-XII of FIG. 10.

FIG. 13 and FIG. 14 are graphs showing a contamination degree of a liquid crystal layer according to a contact time of a photo-curable material and a liquid crystal layer.

FIG. 15 to FIG. 17 are representative views showing a display device according to a reference example.

FIG. 18 to FIG. 20 are representative views showing a display device formed by using a slot die coater according to an exemplary embodiment of the present invention.

FIG. 21 to FIG. 23 are graphs showing a thickness of an encapsulation layer near an edge of a display device.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Accordingly, the drawings are not to scale. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

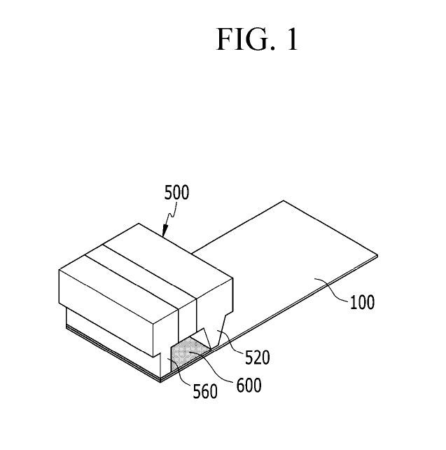

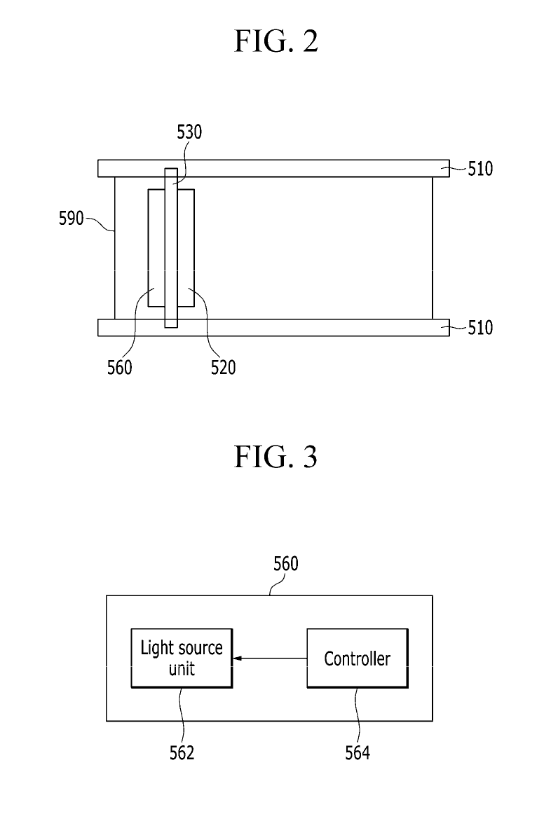

First, a slot die coater according to an exemplary embodiment of the present invention will be described with reference to FIG. 1 and FIG. 2.

FIG. 1 is a perspective view of a portion of a slot die coater according to an exemplary embodiment of the present invention, and FIG. 2 is a top plan view of a slot die coater according to an exemplary embodiment of the present invention.

A slot die coater 500 according to an exemplary embodiment of the present invention includes a slit nozzle 520 and an exposure unit 560 positioned near the slit nozzle 520.

The slit nozzle 520 supplies a photo-curable material to form a coating layer 600 on a substrate 100. The photo-curable material is made of a liquid to be substantially uniformly applied on the substrate 100.

The exposure unit 560 irradiates light to harden the coating layer 600. As the light is irradiated upon the photo-curable coating layer 600, the formerly-liquid coating layer 600 is hardened and becomes rigid. The photo-curable material may be made of an ultraviolet ray-hardening material, and the light irradiated by the exposure unit 560 may be ultraviolet light.

The exposure unit 560 is affixed or otherwise coupled to the slit nozzle 520. Accordingly, if the slit nozzle 520 is moved, the exposure unit 560 is also moved in the same direction and by the same amount. The photo-curable material supplied from the slit nozzle 520 is directly hardened by the exposure unit 560 moved along with the slit nozzle 520. That is, the photo-curable material is hardened directly after it is deposited, such that subsequently-deposited layers contacting the coating layer 600 may be prevented from being contaminated.

The exposure unit 560 starts to emit irradiating light directly after the photo-curable material is supplied, and the irradiation of the light is finished after the supply of the photo-curable material is stopped and all or substantially all of the photo-curable material is cured.

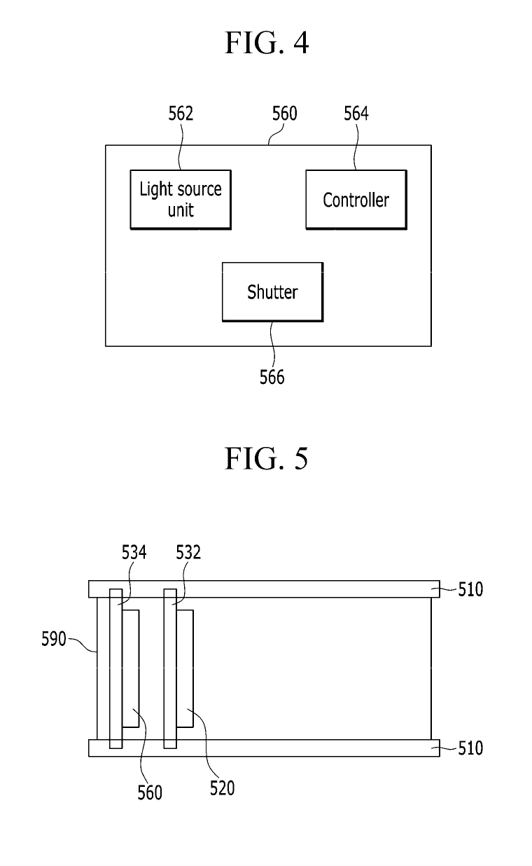

Next, the exposure unit 560 will be described with reference to FIG. 3 and FIG. 4.

FIG. 3 and FIG. 4 are block diagrams of an exposure unit of a slot die coater according to an exemplary embodiment of the present invention.

Firstly, referring to FIG. 3, the exposure unit 560 includes a light source unit 562 generating and supplying the light, and a controller 564 controlling the light emitted by the light source unit 562.

The light source unit 562 may be, for example, a light emitting diode (LED) or a high pressure mercury lamp. The light source unit 562 may be formed of various light emitting members that are capable of supplying the ultraviolet rays.

The controller 564 controls on/off switching of the light source unit 562. If the controller 564 turns on power to the light source unit 562, the light source unit 562 irradiates the light. If the controller 564 turns off power to the light source unit 562, the light source unit 562 stops its light irradiation.

Next, referring to FIG. 4, the exposure unit 560 may include the light source unit 562 generating and supplying the light, the controller 564 controlling the light emitted by the light source unit 562, and a shutter 566 blocking the light supplied from the light source unit 562.

The shutter 566 is positioned to cover the area where the light of the light source unit 562 is emitted.

The controller 564 controls the light blocking function of the shutter 566. In a state that the power of the light source unit 562 is turned on, if the controller 564 activates the shutter 566, the light emitted from the light source unit 562 is blocked by the shutter 566. In a state that the power of the light source unit 562 is turned on, if the controller 564 does not activate the shutter 566, the light emitted from the light source unit 562 may be emitted by the exposure unit 560 to fall incident upon the coating layer 600.

In a method of controlling the light supply by using the shutter 566, a delay according to a preheating time of the light source unit 562 may be prevented.

Again referring to FIG. 1 and FIG. 2, the slot die coater 500 according to an exemplary embodiment of the present invention further includes a gantry 530 supporting the slit nozzle 520, and a rail 510 mounted with the gantry 530.

The slit nozzle 520 may be affixed or otherwise coupled to the gantry 530. For example, the slit nozzle 520 may be attached to the gantry 530. The gantry 530 is mounted on the rail 510 to be moved along a direction that the rail 510 is formed. As the slit nozzle 520 is also moved according to the movement of the gantry 530, the photo-curable material may be deposited upon the substrate 100.

The rail 510 is disposed at both side edges of the gantry 530. Two rails may be disposed in parallel at both sides of the gantry 530.

The direction in which the slit nozzle 520 applies the photo-curable material may be substantially the same as the direction in which the exposure unit 560 irradiates the light. A stage 590 is placed at the position where the photo-curable material and the light are supplied. Accordingly, the direction in which the photo-curable material and the light are supplied is substantially perpendicular to the stage 590. The substrate 100 is mounted to the stage 590. The stage 590 is formed as an approximate quadrangle, and the rail 510 may be fixed to two opposing side surfaces of the stage 590.

For example, the stage 590 includes a first edge and a second edge facing each other, and a third edge and a fourth edge facing each other. At this time, the rail 510 may be respectively disposed at the first edge and the second edge of the stage 590. Also, during operation, the gantry 530 is moved toward the fourth edge from the third edge of the stage 590. The slit nozzle 520 and the exposure unit 560 are also moved toward the fourth edge from the third edge of the stage 590 along with the movement of the gantry 530. So as to not affect the stage 590, the substrate 100, etc., by the movement of the slit nozzle 520 and the exposure unit 560, an interval or space between the slit nozzle 520 and the stage 590 and an interval/space between the exposure unit 560 and the stage 590 may be substantially uniformly maintained.

The exposure unit 560 may be directly affixed to the slit nozzle 520. That is, one side surface of the exposure unit 560 may be adhered to one side surface of the slit nozzle 520. Further, the exposure unit 560 may be affixed or otherwise coupled to the slit nozzle 520 by other means. For example, the slit nozzle 520 is affixed to the gantry 530 and the exposure unit 560 is also affixed to the gantry 530 such that the exposure unit 560 may be indirectly fixed to the slit nozzle 520.

When coating a substrate 100 of a very large size, the size (i.e. width) of the stage 590 is increased such that the size of the slit nozzle 520 is also increased. In this case, a single gantry 530 may be insufficient to support the slit nozzle 520 and the exposure unit 560. Accordingly, in this case, a plurality of gantries 530 may be provided to respectively support the slit nozzle 520 and the exposure unit 560.

Next, referring to FIG. 5, a slot die coater according to another exemplary embodiment of the present invention including a plurality of gantries will be described.

FIG. 5 is a top plan view of a slot die coater according to another exemplary embodiment of the present invention.

As shown in FIG. 5, two gantries are mounted to the rail 510. The gantries include a first gantry 532 and a second gantry 534. The slit nozzle 520 is fixed to the first gantry 532 and the exposure unit 560 is fixed to the second gantry 534. The first gantry 532 and the second gantry 534 are mounted on the same rail 510 such that they may both be moved in the same direction.

Initially, the slit nozzle 520 deposits the photo-curable material according to the movement of the first gantry 532. Next, as the second gantry 534 is moved, the exposure unit 560 irradiates the light to harden the photo-curable material. By simultaneously moving the first gantry 532 and the second gantry 534, the photo-curable material may be hardened directly after it is deposited.

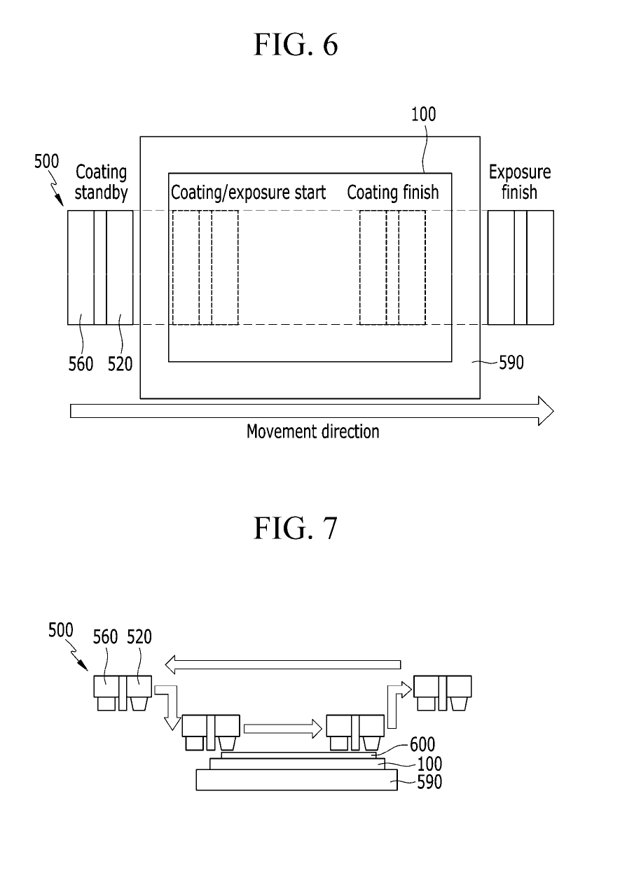

Next, a method of coating the photo-curable material by using the slot die coater according to an exemplary embodiment of the present invention will be described with reference to FIG. 6 and FIG. 7.

FIG. 6 is a top plan view showing a process of moving a slit nozzle of a slot die coater and an exposure unit according to an exemplary embodiment of the present invention, and FIG. 7 is a cross-sectional view showing a process of moving a slit nozzle of a slot die coater and an exposure unit according to an exemplary embodiment of the present invention. In FIG. 6 and FIG. 7, arrows represent a movement direction of the slit nozzle and the exposure unit.

First, the substrate 100 is mounted to the stage 590. Initially, as shown in a left edge of FIG. 6 and FIG. 7, the slit nozzle 520 and the exposure unit 560 are in a standby state. In this case, the slit nozzle 520 does not output any photo-curable material, and the exposure unit 560 is in a state that the light is not emitted either.

Next, the slit nozzle 520 and the exposure unit 560 are moved in the direction of the arrows. While moving, a height of the slit nozzle 520 and the exposure unit 560 is decreased. That is, in the view of FIG. 7, a vertical distance to the substrate 100 is decreased. If the slit nozzle 520 reaches one edge of the substrate 100, the slit nozzle 520 begins to output photo-curable material. The supplied photo-curable material is deposited upon the substrate 100 to form the coating layer 600.

Next, if the exposure unit 560 reaches one edge of the substrate 100, it begins to irradiate light. The irradiated light hardens the photo-curable material forming the coating layer 600. Accordingly, the coating layer 600 is hardened or made rigid.

Next, the slit nozzle 520 and the exposure unit 560 are moved. The slit nozzle 520 and the exposure unit 560 are fixed to the gantry such that the slit nozzle 520 and the exposure unit 560 are also moved along with the movement of the gantry. While the slit nozzle 520 is moved across the substrate 100, the photo-curable material is sequentially supplied, i.e. deposited in an even layer across the surface of the substrate 100. While the exposure unit 560 is also moved across the substrate 100, its light is irradiated upon the deposited photo-curable material. Thus, while the exposure unit 560 follows the slit nozzle 520, the photo-curable material is hardened. Accordingly, by hardening the photo-curable material directly after it is deposited on the substrate 100, other subsequent layers contacting the coating layer 600 may be prevented from being contaminated.

If the slit nozzle 520 reaches the other edge of the substrate 100 (i.e. the rightmost edge of substrate 100 in the views of FIGS. 6 and 7), the supply of the photo-curable material is stopped. Also, if the exposure unit 560 passes the other edge of the substrate 100, the light irradiation is stopped. If the photo-curable material and the light irradiation are stopped, the height of the slit nozzle 520 and the exposure unit 560 is again increased, as in FIG. 7. That is, the distance from the substrate 100 is increased.

Next, the movement direction of the slit nozzle 520 and the exposure unit 560 is changed such that they are again returned to their starting point, or the edge of the substrate 100 at which material deposition began. The substrate 100 where the formation of the coating layer 600 is completed is separated from the stage 590, and a new substrate 100 is mounted to the stage 590.

The above has described one exemplary method in which the slit nozzle and the exposure unit are mounted on the gantry to be moved. However, the present invention is not limited thereto. For example, in other embodiments, the coating layer may be entirely formed on the substrate through the movement of the stage, without moving either the slit nozzle or the exposure unit. That is, instead of moving the slit nozzle 520 and exposure unit 560 across the substrate 100 as in FIGS. 6-7, the slit nozzle 520 and exposure unit 560 may instead be stationary, and the stage 590 may be configured with actuators allowing it to move back and forth underneath the slit nozzle 520 and exposure unit 560. In this manner, photo-curable material may be deposited and cured upon the substrate 100 as the stage 590 moves it along underneath the nozzle 520/unit 560.

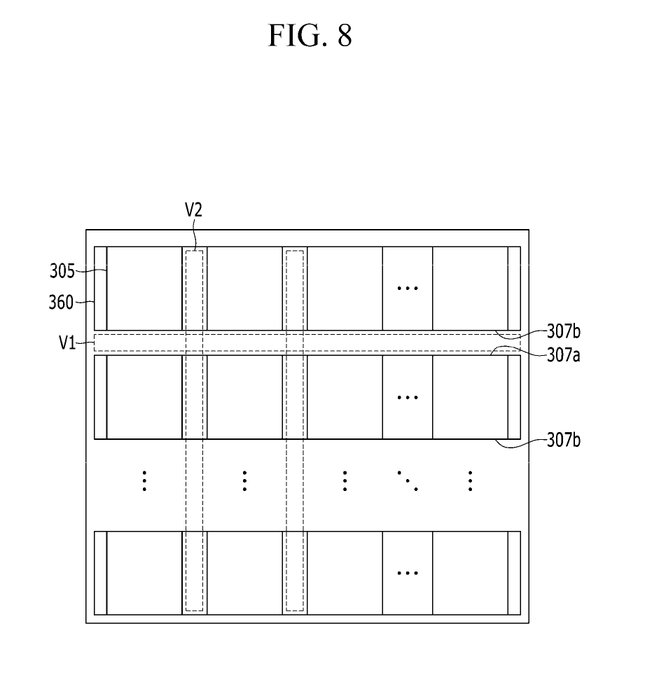

The slot die coater according to an exemplary embodiment of the present invention may be used to manufacture a display device. Hereafter, the display device manufactured by using the slot die coater according to an exemplary embodiment of the present invention will be described with reference to FIG. 8 to FIG. 12.

Firstly, the display device manufactured by using the slot die coater according to an exemplary embodiment of the present invention will be described with reference to FIG. 8.

FIG. 8 is a top plan view of a display device manufactured by using a slot die coater according to an exemplary embodiment of the present invention.

The display device according to an exemplary embodiment of the present invention includes a substrate 110 made of a material such as glass or plastic.

A microcavity 305 covered by a roof layer 360 is formed on the substrate 110. The roof layer 360 extends in a row direction, and a plurality of microcavities 305 are formed under one roof layer 360.

The microcavities 305 may be arranged in a matrix form, a first valley V1 is formed between the microcavities 305 adjacent in a row direction (i.e. between adjacent rows of microcavities 305), and a second valley V2 is formed between the microcavities 305 adjacent in a column direction (i.e. between adjacent columns of microcavities 305).

Adjacent roof layers 360 may be separated from each other by the first valleys V1. Sides of the microcavities 305 are open, and exposed at edges of the first valleys V1. These open, exposed sides are referred to as injection holes 307a and 307h.

The injection holes 307a and 307b are formed at both edges of the microcavities 305. The injection holes 307a and 307b include a first injection hole 307a and a second injection hole 307b. The first injection hole 307a is formed so as to expose a lateral surface of a first edge of the microcavity 305, and the second injection hole 307b is formed so as to expose another lateral surface of a second edge of the microcavity 305. The lateral surface of the first edge and the lateral surface of the second edge of the microcavity 305 face each other.

Each roof layer 360 lifts upward and away from the substrate 110 between the adjacent second valleys V2, thus forming the microcavities 305. That is, the roof layer 360 is the upper surface of each microcavity 305, and is open at its sides to form the injection holes 307a and 307b.

The aforementioned structure of the display device according to the exemplary embodiment of the present invention is just an example, and various modifications are feasible. For example, positions and arrangements of the microcavity 305, the first valley V1, and the second valley V2 may be changed, the plurality of roof layers 360 may be connected to each other in the first valley V1, and instead of having the second valleys V2, adjacent microcavities 305 may be connected to each other.

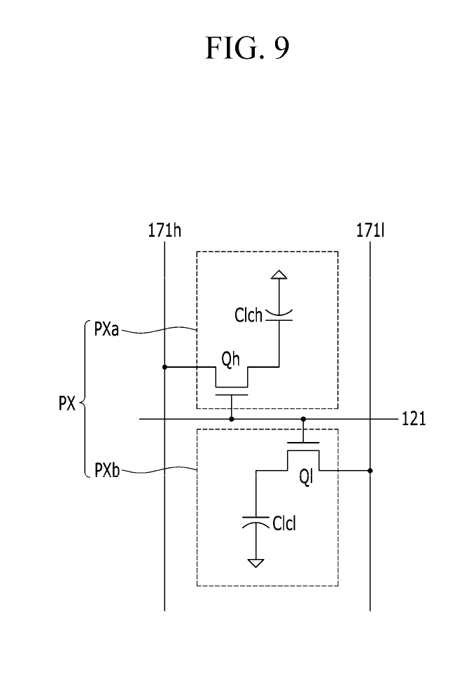

Hereinafter, one pixel of the display device manufactured by using the slot die coater according to the exemplary embodiment of the present invention will be schematically described with reference to FIG. 9.

FIG. 9 is an equivalent circuit diagram of one pixel of a display device manufactured by using a slot die coater according to an exemplary embodiment of the present invention.

The display device manufactured by using the slot die coater according to an exemplary embodiment of the present invention includes a plurality of signal lines 121, 171h, and 171l, and a pixel PX connected thereto. Although not shown, the plurality of pixels PX may be arranged in a matrix form including a plurality of pixel rows and a plurality of pixel columns.

Each pixel PX may include a first subpixel PXa and a second subpixel PXb. The first subpixel PXa and the second subpixel PXb may be vertically arranged. In this case, the first valley V1 may be oriented in a pixel row direction, positioned between the first subpixel PXa and the second subpixel PXb, and the second valley V2 may be oriented perpendicular to first valley V1 and positioned between pixel columns.

The signal lines 121, 171h, and 171l include a gate line 121 for transmitting a gate signal, and a first data line 171h and a second data line 171l for transmitting different data voltages.

The display device according to the exemplary embodiment of the present invention includes a first switching element Qh connected to the gate line 121 and the first data line 171h, and a second switching element Ql connected to the gate line 121 and the second data line 171l.

A first liquid crystal capacitor Clch connected to the first switching element Qh is formed in the first subpixel PXa, and a second liquid crystal capacitor Clcl connected to the second switching element Ql is formed in the second subpixel PXb.

A first terminal of the first switching element Qh is connected to the gate line 121, a second terminal thereof is connected to the first data line 171h, and a third terminal thereof is connected to an electrode of the first liquid crystal capacitor Clch.

A first terminal of the second switching element Ql is connected to the gate line 121, a second terminal thereof is connected to the second data line 171l, and a third terminal thereof is connected to an electrode of the second liquid crystal capacitor Clcl.

An operation of the liquid crystal display according to the exemplary embodiment of the present invention will now be described. When a gate-on voltage is applied to the gate line 121, the first switching element Qh and the second switching element Ql connected to the gate line 121 are turned on, and the first and second liquid crystal capacitors Clch and Clcl are charged with different data voltages transmitted through the first and second data lines 171h and 171l. The data voltage transmitted by the second data line 171l may be lower than the data voltage transmitted by the first data line 171h. Accordingly, the second liquid crystal capacitor Clcl can be charged with a lower voltage than that of the first liquid crystal capacitor Clch, thereby improving side visibility.

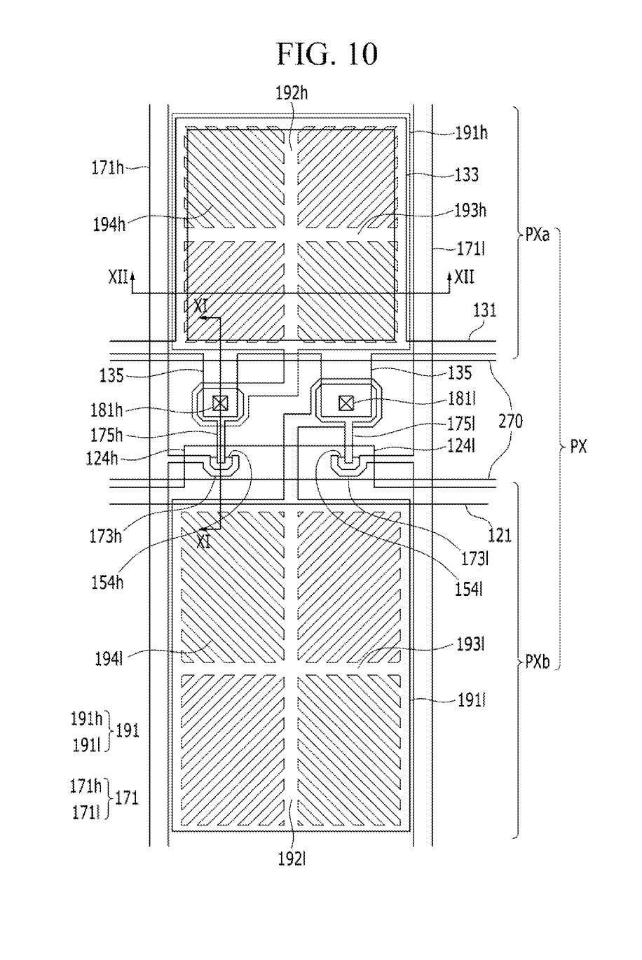

Hereinafter, a structure of one pixel of the display device manufactured by using the slot die coater according to the exemplary embodiment of the present invention will be described with reference to FIG. 10 to FIG. 12.

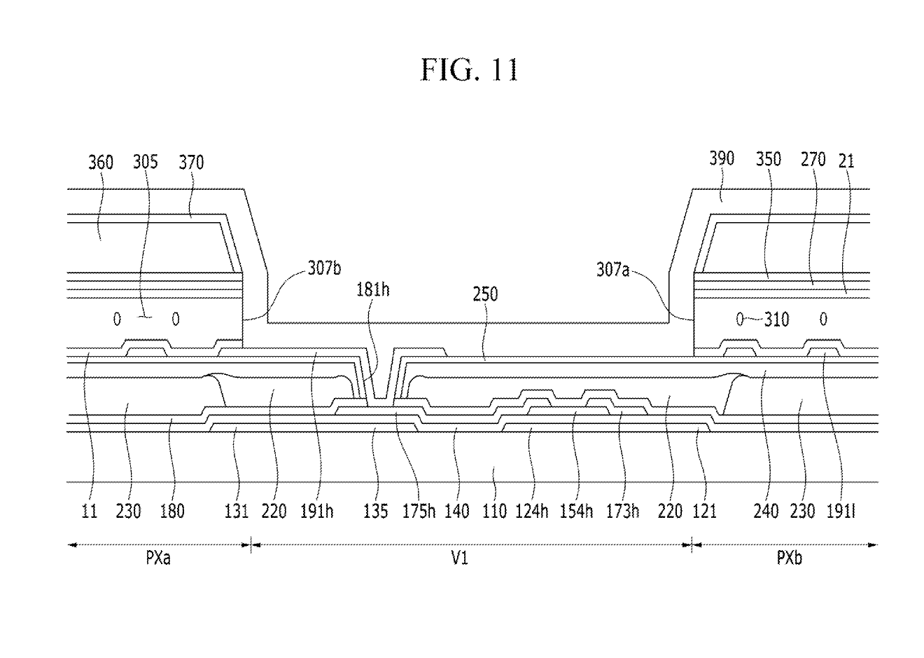

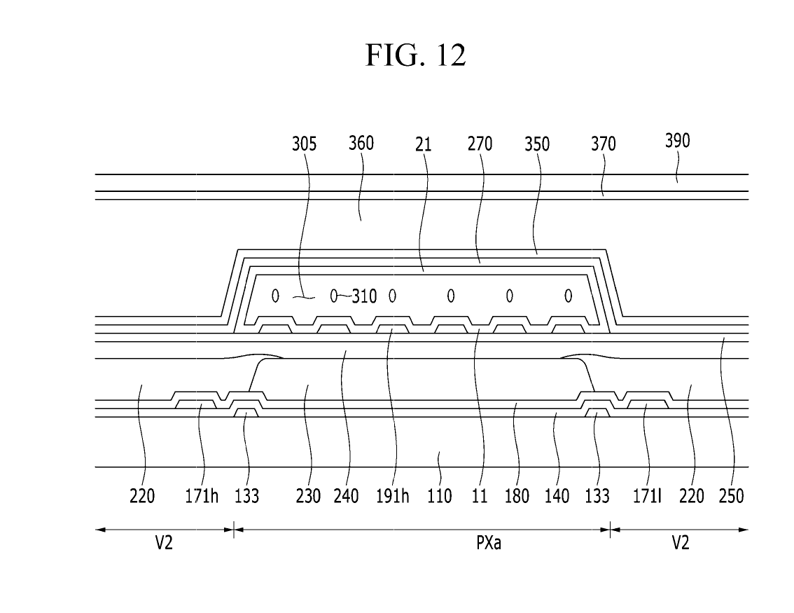

FIG. 10 is a layout view of a portion of a display device manufactured by using a slot die coater according to an exemplary embodiment of the present invention, and FIG. 11 is a cross-sectional view taken along line XI-XI of FIG. 10. FIG. 12 is a cross-sectional view taken along line XII-XII of FIG. 10.

Referring to FIG. 10 to FIG. 12, the gate line 121 and a first gate electrode 124h and a second gate electrode 124l protruding from the gate line 121 are formed on the substrate 110.

The gate line 121 mainly extends in a first direction, and transmits a gate signal. The gate line 121 is positioned between the two microcavities 305 which are adjacent in a column direction. That is, the gate line 121 is positioned at, or at least partially in, the first valley V1. The first gate electrode 124h and the second gate electrode 124l upwardly protrude from the gate line 121 in plan view (i.e., the view of FIG. 10). The first gate electrode 124h and the second gate electrode 124l are connected to each other to form one protrusion. However, the present invention is not limited thereto, and the plan shape of the first gate electrode 124h and the second gate electrode 124l may be variously modified.

A storage electrode line 131 and storage electrodes 133 and 135 protruding from the storage electrode line 131 may be further formed on the substrate 110.

The storage electrode line 131 generally extends in a direction parallel to the gate line 121, and is formed to be spaced apart from the gate line 121. A predetermined voltage may be applied to the storage electrode line 131. The storage electrode 133 protruding from the storage electrode line 131 is formed to enclose the edge of the first subpixel PXa. The storage electrode 135 protruding under the storage electrode line 131 in the view of FIG. 10 is formed to be adjacent or proximate to the first gate electrode 124h and the second gate electrode 124l.

A gate insulating layer 140 is formed on the gate line 121, the first gate electrode 124h, the second gate electrode 124l, the storage electrode line 131, and the storage electrodes 133 and 135. The gate insulating layer 140 may be formed of an inorganic insulating material, such as a silicon nitride (SiNx) and/or a silicon oxide (SiOx). Further, the gate insulating layer 140 may be formed of a single layer or in a multilayer configuration.

A first semiconductor 154h and a second semiconductor 154l are formed on the gate insulating layer 140. The first semiconductor 154h may be positioned on the first gate electrode 124h, and the second semiconductor 154l may be positioned on the second gate electrode 124l. The first semiconductor 154h may be further formed under the first data line 171h, and the second semiconductor 154l may be further formed under the second data line 171l. The first semiconductor layer 154h and the second semiconductor 154l may be formed of amorphous silicon, polycrystalline silicon, a metal oxide, or the like.

An ohmic contact member (not illustrated) may be formed on each of the first semiconductor 154h and the second semiconductor 154l. The ohmic contact members may be made of a silicide or a material such as n+ hydrogenated amorphous silicon on which an n-type impurity is doped at a high concentration.

The first data line 171h, the second data line 171l, a first source electrode 173h, a first drain electrode 175h, a second source electrode 173l, and a second drain electrode 175l are formed on the first semiconductor 154h, the second semiconductor 154l, and the gate insulating layer 140.

The first data line 171h and the second data line 171l transfer data signals, and mainly extend in a second direction to cross the gate line 121 and the storage electrode line 131. The data line 171 is positioned between two adjacent columns of microcavities 305. That is, the data line 171 is positioned at the second valley V2.

The first data line 171h and the second data line 171l can transmit different data voltages. For example, the data voltage transmitted by the second data line 171l may be lower than the data voltage transmitted by the first data line 171h.

The first source electrode 173h is formed so as to protrude from the first data line 171h under the first gate electrode 124h, and the second source electrode 173l is formed so as to protrude from the second data line 171l under the second gate electrode 124l. Each of the first drain electrode 175h and the second drain electrode 175l has one wide end portion and another rod-shaped end portion. The wide end portions of the first drain electrode 175h and the second drain electrode 175l overlap the storage electrode 135 protruding from the storage electrode line 131. Each of the rod-shaped end portions of the first drain electrode 175h and the second drain electrode 175l is partially surrounded by the first source electrode 173h and the second source electrode 173l.

The first and second gate electrodes 124h and 124l, the first and second source electrodes 173h and 173l, and the first and second drain electrodes 175h and 175l collectively form first and second thin film transistors (TFT) Qh and Ql together with the first and second semiconductors 154h and 154l, and channels of the thin film transistors are formed in the semiconductors 154h and 154l between the source electrodes 173h and 173l and the drain electrodes 175h and 175l, respectively.

A passivation layer 180 is formed on the exposed portion of the first semiconductor 154h, the first data line 171h, the second data line 171l, the first source electrode 173h, the first drain electrode 175h, and the exposed portion of the second semiconductor 154l, the second source electrode 173l, and the second drain electrode 175l. The passivation layer 180 may be formed of an organic insulating material or an inorganic insulating material, and may be formed of a single layer or a multilayer.

A color filter 230 is formed in each pixel PX on the passivation layer 180.

The color filter 230 may include a red color filter, a green color filter, and a blue color filter representing three primary colors. The color filter 230 is not limited to the three primary colors of red, green, and blue, and may represent any other colors such as cyan, magenta, yellow, and a white-containing color. In some embodiments, the color filter 230 may not be present in the first valley V1.

A light blocking member 220 is formed in a region between neighboring color filters 230. The light blocking member 220 is formed on a boundary of the pixel PX and the thin film transistor, to prevent light leakage. That is, the light blocking member 220 may be formed in the first valley V1 and the second valley V2. The color filter 230 and the light blocking member 220 may partially overlap each other.

A first insulating layer 240 may be further formed on the color filter 230 and the light blocking member 220. The first insulating layer 240 may be formed of an organic insulating material, and may serve to planarize the color filters 230.

A second insulating layer 250 may be further formed on the first insulating layer 240. The second insulating layer 250 may be formed of an inorganic insulating material, and may serve to protect the color filter 230 and the first insulating layer 240.

A first contact hole 181h through which the wide end portion of the first drain electrode 175h is exposed, and a second contact hole 181l through which the wide end portion of the second drain electrode 175l is exposed, are formed in the passivation layer 180, the first insulating layer 240, and the second insulating layer 250.

A pixel electrode 191 is formed on the second insulating layer 250. The pixel electrode 191 may be formed of a transparent metal material, such as indium-tin oxide (ITO) and/or indium-zinc oxide (IZO).

The pixel electrode 191 includes a first subpixel electrode 191h and a second subpixel electrode 191l which are separated from each other with the gate line 121 and the storage electrode line 131 interposed therebetween. The first subpixel electrode 191h and the second subpixel electrode 191l are disposed within pixel PX and on opposing sides of the gate line 121 and the storage electrode line 131. That is, the first sub-pixel electrode 191h and the second sub-pixel electrode 191l are separated from each other with the first valley V1 interposed therebetween, and the first sub-pixel electrode 191h is positioned in the first sub-pixel PXa and the second sub-pixel electrode 191l is positioned in the second sub-pixel PXb.

The first sub-pixel electrode 191h is connected to the first drain electrode 175h through the first contact hole 181h, and the second sub-pixel electrode 191l is connected to the second drain electrode 175l through the second contact hole 181l. Accordingly, when the first thin film transistor Qh and the second thin film transistor Ql are in an on-state, the first sub-pixel electrode 191h and the second sub-pixel electrode 191l receive different data voltages from the first drain electrode 175h and the second drain electrode 175l, respectively. An electric field may thus be formed between the pixel electrode 191 and a common electrode 270.

The overall shape of each of the first sub-pixel electrode 191h and the second sub-pixel electrode 191l is a quadrangle, and the first sub-pixel electrode 191h and the second sub-pixel electrode 191l include cross-shaped stem portions formed by horizontal stem portions 193h and 193l and vertical stem portions 192h and 192l which cross the horizontal stem portions 193h and 193l. Further, each of the first sub-pixel electrode 191h and the second sub-pixel electrode 191l includes a plurality of micro-branch portions 194h and 194l.

The pixel electrode 191 is divided into four sub-regions by the horizontal stem portions 193h and 193l and the vertical stem portions 192h and 192l. The micro-branch portions 194h and 194l obliquely extend from the horizontal stem portions 19h1 and 193l and the vertical stem portions 192h and 192l, and the extension direction may form an angle of approximately 45° or 135° with the gate line 121 or the horizontal stem portions 193h and 193l. Further, the directions in which the micro-branch portions 194h and 194l in two adjacent sub-regions extend may be orthogonal to each other.

In the present exemplary embodiment, the first sub-pixel electrode 191h and the second sub-pixel electrode 191l may further include outer stem portions surrounding outer sides of the first sub-pixel PXa and the second sub-pixel PXb, respectively.

The positions, shapes, and orientations of the pixel, the structure of the thin film transistor, the pixel electrode, and any components thereof described above are one example, the present invention is not limited thereto, and various modifications are feasible.

The common electrode 270 is formed on the pixel electrode 191 so as to be spaced apart from the pixel electrode 191 by a predetermined distance. The microcavity 305 is formed between the pixel electrode 191 and the common electrode 270. That is, the microcavity 305 is surrounded by the pixel electrode 191 below and the common electrode 270 above. The common electrode 270 is formed in the row direction and is disposed on the microcavity 305 and in the second valley V2. The common electrode 270 is formed to contact the top surface and the side of the microcavity 305. The width and area of the microcavity 305 may be variously modified according to a size and resolution of the display device.

In each pixel PX, the common electrode 270 is formed to be separated from the substrate 110, thereby forming the microcavity 305, but in the second valley V2, the common electrode 270 is formed to be attached on the substrate 110. In the second valley V2, the common electrode 270 is formed immediately above the second insulating layer 250.

The common electrode 270 may be formed of a transparent metal material such as indium-tin oxide (ITO) and indium-zinc oxide (IZO). A predetermined voltage may be applied to the common electrode 270, and an electric field may be formed between the pixel electrode 191 and the common electrode 270.

A first alignment layer 11 is formed on the pixel electrode 191. The first alignment layer 11 may also be formed directly on those portions of the first insulating layer 240 that are not covered by the pixel electrode 191.

A second alignment layer 21 is formed under the common electrode 270 so as to face the first alignment layer 11.

The first alignment layer 11 and the second alignment layer 21 may be formed as vertical alignment layers, and may be formed of an alignment material such as polyamic acid, polysiloxane, and polyimide. The first and second alignment layers 11 and 21 may be connected on a side wall of the microcavity 305, at ends thereof.

A liquid crystal layer formed of liquid crystal molecules 310 is formed in the microcavity 305 positioned between the pixel electrode 191 and the common electrode 270. The liquid crystal molecules 310 have negative dielectric anisotropy, and may be erected in a vertical direction on the substrate 110 when an electric field is not applied. That is, vertical alignment may be implemented.

The first sub-pixel electrode 191h and the second sub-pixel electrode 191l, to which the data voltage is applied, generate an electric field together with the common electrode 270 to determine a direction of the liquid crystal molecules 310 positioned in the microcavity 305 between the two electrodes 191 and 270. Luminance of light passing through the liquid crystal layer is changed according to the thusly determined direction of the liquid crystal molecules 310.

A third insulating layer 350 may be further formed on the common electrode 270. The third insulating layer 350 is formed on the common electrode 270, and the edge of the common electrode 270 is formed to have a step shape, so that an edge of the third insulating layer 350 may also be formed to have a step shape. A portion of the third insulating layer 350 which is adjacent to the second valley V2 is formed to have the step shape.

The third insulating layer 350 may be formed of an inorganic insulating material, such as a silicon nitride (SiNx) and/or a silicon oxide (SiOx), and may also be omitted if necessary.

The roof layer 360 is formed on the third insulating layer 350. The roof layer 360 may be formed of an organic material. The microcavity 305 is formed under the roof layer 360, and the roof layer 360 may be hardened by a hardening process to maintain the shape of the microcavity 305. The roof layer 360 is formed in the row direction and is disposed on the microcavity 305 and in the second valley V2. Thus, the roof layer 360 is formed to cover both the upper surface and lateral surfaces of the microcavity 305. The roof layer 360 may be hardened by a hardening process to maintain the shape of the microcavity 305. The roof layer 360 is formed to be spaced apart from the pixel electrode 191 with the microcavity 305 interposed therebetween.

The common electrode 270 and the roof layer 360 are formed to expose the sides of the microcavity 305, and portions where the microcavity 305 is not covered by the common electrode 270 and the roof layer 360 are injection holes 307a and 307b. The injection holes 307a and 307b include a first injection hole 307a through which a first side of the microcavity 305 is exposed, and a second injection hole 307b through which a second side of the microcavity 305 is exposed. The first edge and the second edge face each other, and for example, in plan view, the first edge may be an upper edge of the microcavity 305, and the second edge may be a lower edge of the microcavity 305. The injection holes 307a and 307b expose those sides of the microcavity 305 which are adjacent to the first valley V1. The microcavities 305 are exposed by the injection holes 307a and 307b, so that an alignment solution, a liquid crystal material, or the like may be injected into the microcavities 305 through the injection holes 307a and 307b.

A fourth insulating layer 370 may be further formed on the roof layer 360. The fourth insulating layer 370 may be made of an inorganic insulating material such as a silicon nitride (SiNx) and/or a silicon oxide (SiOx). The fourth insulating layer 370 may be formed to cover the top and the sides of the roof layer 360. The fourth insulating layer 370 serves to protect the roof layer 360, and may be omitted if necessary.

An encapsulation layer 390 may be formed on the fourth insulating layer 370. The encapsulation layer 390 is formed to cover the injection holes 307a and 307b. That is, the encapsulation layer 390 may seal the microcavity 305 so that the liquid crystal molecules 310 formed in the microcavity 305 are not discharged to the outside.

The encapsulation layer 390 is formed of the above mentioned photo-curable material. The encapsulation layer 390 contacts the liquid crystal molecules 310 and may thus contaminate the liquid crystal layer. However, the encapsulation layer 390 is formed by using the slot die coater according to an exemplary embodiment of the present invention, so that contamination of the liquid crystal layer may be prevented. The slot die coater according to an exemplary embodiment of the present invention may harden the photo-curable material by the exposure unit directly after the photo-curable material is supplied on the substrate 110 through the slit nozzle. Accordingly, the photo-curable material is hardened before the liquid crystal layer is contaminated, so that the liquid crystal layer may be prevented from being contaminated by the encapsulation layer 390.

The encapsulation layer 390 may be formed as a multilayer structure, such as a double layer and a triple layer. Any composition of these multilayer structures is contemplated. In one example, the double layer is made of two layers of different materials, and the triple layer is made of three layers, where materials of adjacent layers are different from each other. For example, the encapsulation layer 390 may include a layer made of an organic insulating material and a layer made of an inorganic insulating material.

Although not illustrated, polarizers may be further formed on the upper and lower sides of the display device. The polarizers may be configured as a first polarizer and a second polarizer. The first polarizer may be attached to the lower surface of the substrate 110, and the second polarizer may be attached to the encapsulation layer 390.

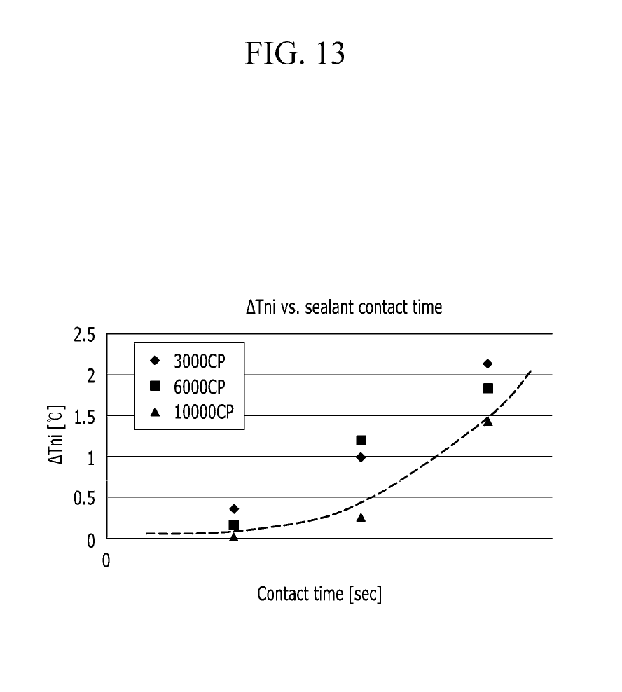

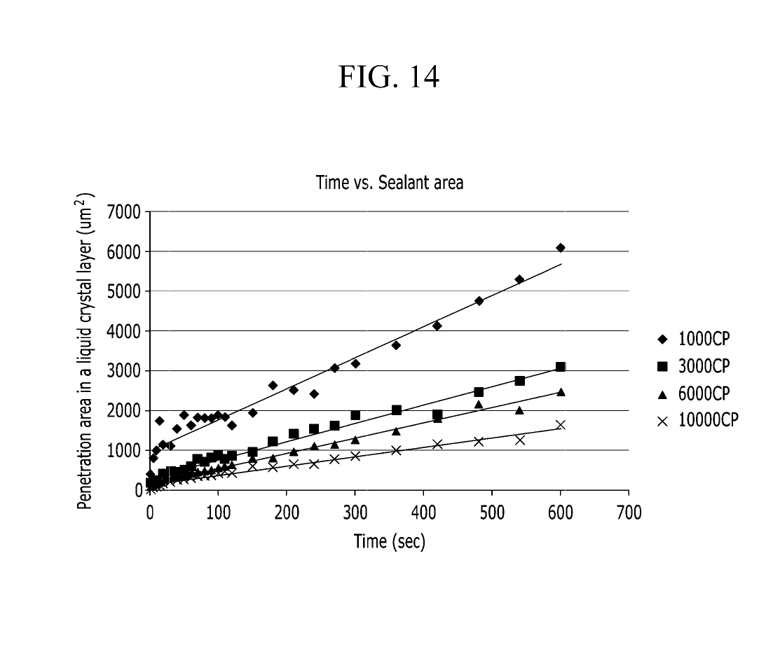

Hereafter, a factor through which the photo-curable material affects the contamination of the liquid crystal layer will be described with reference to FIG. 13 and FIG. 14.

FIG. 13 and FIG. 14 are graphs showing a contamination degree of a liquid crystal layer according to a contact time of a photo-curable material and a liquid crystal layer, as determined by test.

In FIG. 13, to determine the contamination degree of the liquid crystal layer, a change amount ΔTni of a phase transition temperature is used. The phase transition temperature Tni is a temperature at which the liquid crystal layer is changed from a nematic state into an isotropic state. If the liquid crystal layer is contaminated, the phase transition temperature Tni is decreased. Accordingly, an increase in the change amount ΔTni of the phase transition temperature indicates an increase in contamination of the liquid crystal layer.

In the graph of FIG. 13, as a contact time of the photo-curable material and the liquid crystal layer is increased, it is confirmed that the change amount ΔTni of the phase transition temperature is increased. Accordingly, as the duration of contact between the photo-curable material and the liquid crystal layer is increased, the liquid crystal layer is further contaminated.

Also, when a concentration of the photo-curable material is 6000CP compared with 10,000CP, the change amount ΔTni of the phase transition temperature is increased, and when the concentration of the photo-curable material is 3000CP compared with 6000CP, the change amount ΔTni of the phase transition temperature is further increased. Accordingly, it may be confirmed that the liquid crystal layer is further contaminated as the concentration of the photo-curable material is decreased.

FIG. 14 is a graph of the penetration area (when measured in plan view) that the photo-curable material penetrates into the liquid crystal layer as a function of contact time, or the duration of contact between photo-curable material and liquid crystal. A large area by which the photo-curable material penetrates into the liquid crystal layer means that the liquid crystal layer is contaminated to a greater degree over time.

In the graph of FIG. 14, it may be confirmed that the penetration area is increased as the duration of contact between the photo-curable material and the liquid crystal layer increases. Accordingly, it may be confirmed that the liquid crystal layer is further contaminated as the contact time of the photo-curable material and the liquid crystal layer is increased.

Further, it may be confirmed that the penetration area is increased when the concentration of the photo-curable material is 6000CP as compared with 10,000CP, and that the penetration area is increased when the concentration of the photo-curable material is 3000CP as compared with 6000CP. Accordingly, it may be confirmed that the liquid crystal layer is further contaminated as the concentration of the photo-curable material is decreased.

The slot die coater according to an exemplary embodiment of the present invention includes a slit nozzle and exposure unit positioned relatively close together and adjacent to each other, thereby reducing a time between deposition of the photo-curable material and its hardening. Accordingly, the time in which the photo-curable material contacts the liquid crystal layer may be reduced, and the liquid crystal layer may be prevented from being contaminated.

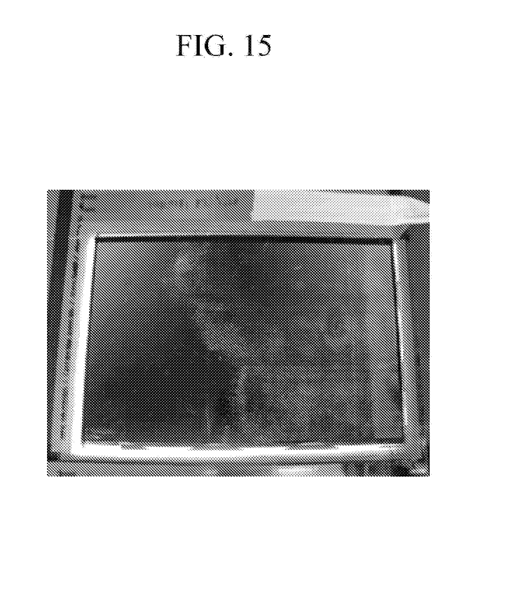

Hereafter, experimental results confirming the performance of the above described slot die coater will be described with reference to FIG. 15 to FIG. 20.

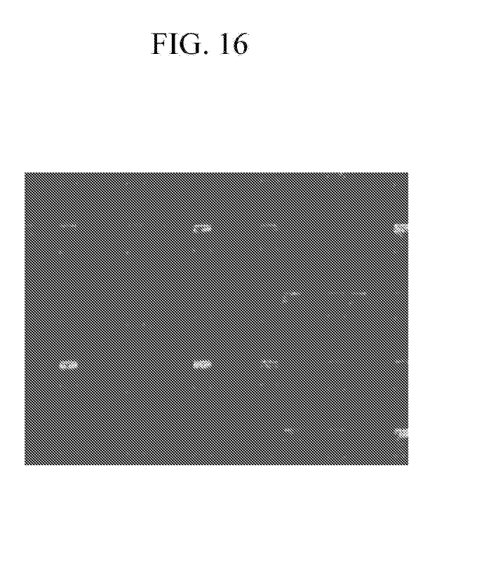

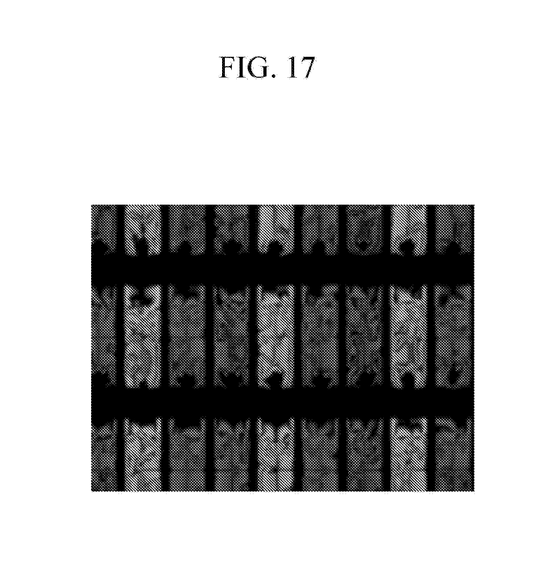

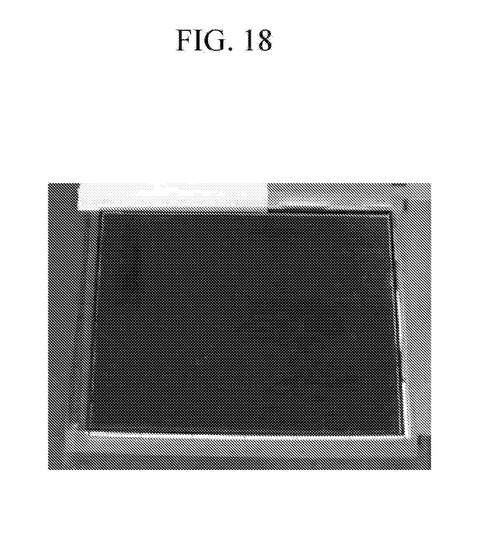

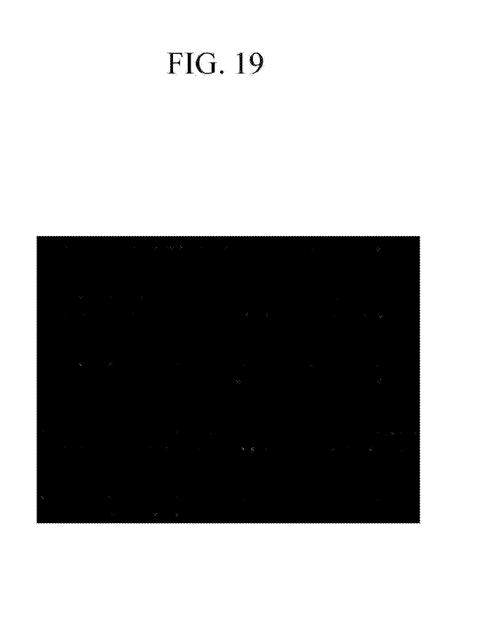

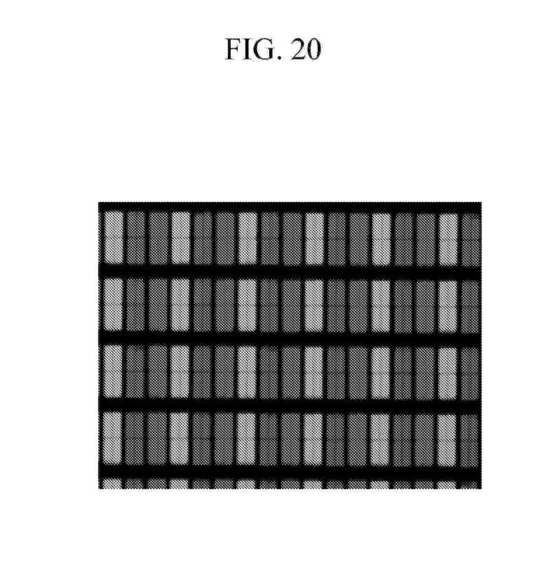

FIG. 15 to FIG. 17 are views describing results of a display device fabricated using conventional coating methods. More specifically, FIG. 15 to FIG. 17 illustrate cases of the display device in which the photo-curable material is first entirely formed on the substrate, and then the photo-curable material is hardened by using a separate exposure apparatus to form the encapsulation layer. FIG. 18 to FIG. 20 are views illustrating a display device formed by using a slot die coater according to an exemplary embodiment of the present invention. FIG. 15 and FIG. 18 are representations of results as measured by eye. FIG. 16 and FIG. 19 illustrate microscopy results measuring an initial state in which no pixel voltage is applied (when an electric field applied to the liquid crystal layer is 0 V). FIG. 17 and FIG. 20 illustrate microscopy results measuring a state in which a voltage is applied to each pixel (when the electric field formed to the liquid crystal layer is 9 V).

In the display device of FIG. 15 to FIG. 17, the time between deposition and hardening of the photo-curable material is sufficiently high that the liquid crystal layer is contaminated, thereby generating visible stains.

In the display device of FIG. 18 to FIG. 20, the photo-curable material is hardened directly after the photo-curable material is supplied on the substrate, such that the liquid crystal layer is not contaminated and a clear screen is displayed.

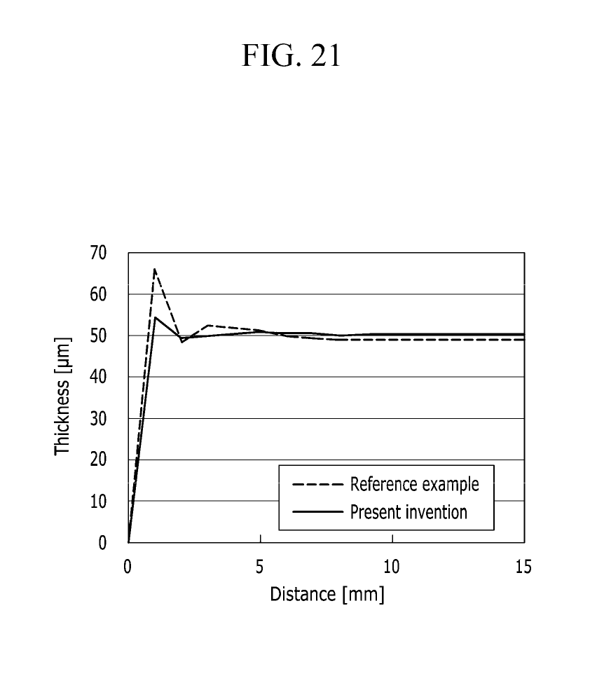

Hereafter, experimental results illustrating the upper surface of an encapsulation layer formed using a slot die coater according to an exemplary embodiment of the present invention will be described with reference to FIG. 21 to FIG. 23.

FIG. 21 to FIG. 23 are graphs showing a thickness of an encapsulation layer near an edge of a display device.

The plan shape of the display device may be an approximate quadrangle, with the display device including the first edge and the second edge facing each other and the third edge and the fourth edge facing each other. The formation of the encapsulation layer starts from the first edge of the display device and progresses toward the second edge.

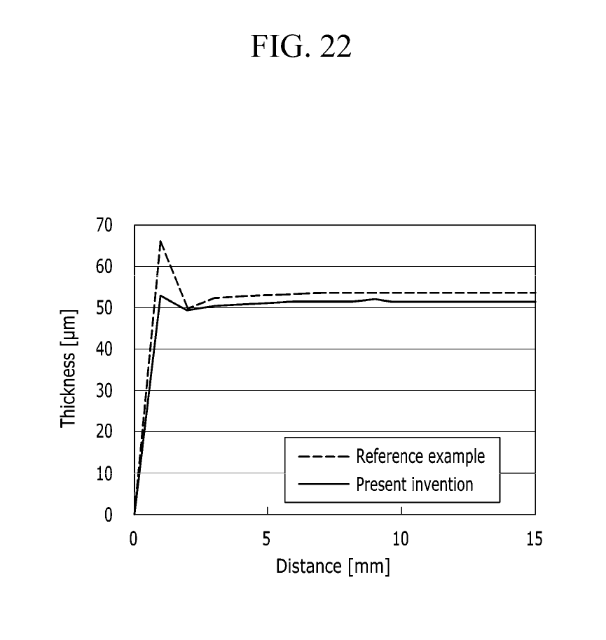

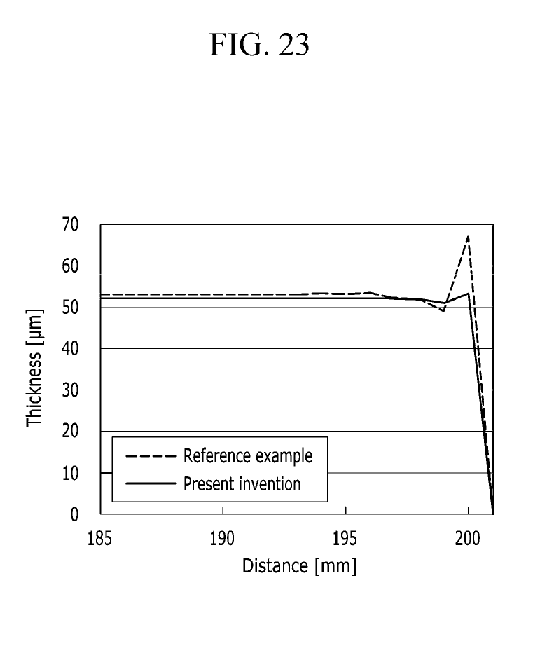

FIG. 21 shows the thickness of the encapsulation layer according to a distance from the third edge, and FIG. 22 and FIG. 23 show the thickness of the encapsulation layer according to distance from the first edge. In FIG. 23, a position where the distance from the first edge is more than 200 mm represents the second edge.

First, referring to the encapsulation layer of the display device according to the reference example, the thickness of the encapsulation layer at the first edge, the second edge, and the third edge is particularly increased as compared with the other portions. When the time between photo-curable material deposition and hardening is increased, the edge of the encapsulation layer is formed.

When forming the encapsulation layer of the display device by using the slot die coater according to an exemplary embodiment of the present invention, it may be confirmed that the thickness of the edge of the encapsulation layer is similar to that of the other portions. In the present exemplary embodiment, the photo-curable material is hardened directly after being supplied on the substrate, such that the upper surface of the encapsulation layer may be more uniformly formed. Accordingly, uniformity of the layer may be improved in a process after forming the encapsulation layer, for example, a polarizer adhering process, etc.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Any features of any embodiments of the invention described or implied herein can be mixed and matched in any manner, so as to produce further embodiments also encompassed by the invention.

<Description of Symbols>

| | |
|---|---|
| 100: substrate | 310: liquid crystal molecule |
| 390: encapsulation layer | 500: slot die coater |
| 510: rail | 520: slit nozzle |
| 530: gantry | 532: first gantry |
| 534: second gantry | |
| 560: exposure unit | 562: light source unit |
| 564: controller | 566: shutter |
| 590: stage | 600: coating layer |

What is claimed is:

1. A slot die coater comprising:
a slit nozzle configured to deposit a photo-curable material upon a substrate; and
an exposure unit coupled to the slit nozzle and positioned adjacent thereto, the exposure unit configured to irradiate light upon the photo-curable material deposited upon the substrate.

2. The slot die coater of claim 1, wherein
the exposure unit is affixed to the slit nozzle.

3. The slot die coater of claim 1, further comprising
a gantry supporting the slit nozzle and the exposure unit.

4. The slot die coater of claim 3, further comprising:
a stage located under positions of the slit nozzle and exposure unit at which the photo-curable material is respectively configured to be deposited and to be irradiated; and
a rail upon which the gantry is mounted.

5. The slot die coater of claim 4, wherein
the rail is coupled to two side surfaces of the stage, the two side surfaces facing each other.

6. The slot die coater of claim 3, wherein
the exposure unit is affixed to the gantry.

7. The slot die coater of claim 3, wherein
the gantry includes a first gantry and a second gantry,
the slit nozzle is affixed to the first gantry, and
the exposure unit is affixed to the second gantry.

8. The slot die coater of claim 1, wherein the exposure unit includes:
a light source unit configured to generate light; and
a controller controlling supply of the generated light.

9. The slot die coater of claim 8, wherein
the light source unit includes one or more of a light emitting diode (LED) and a high pressure mercury lamp configured to generate ultraviolet rays.

10. The slot die coater of claim 8, wherein:
the controller includes a controller configured to switch the light source unit on and off.

11. The slot die coater of claim 8, wherein:
the exposure unit further includes a shutter configured to block light from the light source unit; and
the controller is configured to control the shutter so as to control a blocking of light from the light source unit.

12. The slot die coater of claim 1, wherein
the slot die coater is further configured to deposit the photo-curable material upon the substrate and to irradiate the deposited photo-curable material so as to form a layer of a display device.

13. The slot die coater of claim 12, wherein the display device includes:
a substrate;
a thin film transistor formed on the substrate;
a pixel electrode connected to the thin film transistor;
a roof layer formed on the pixel electrode so as to be spaced apart from the pixel electrode while interposing a plurality of microcavities therebetween;
an injection hole exposing a portion of each microcavity;
a liquid crystal layer positioned within the microcavity; and
an encapsulation layer formed on the roof layer so as to cover the injection hole and to thereby seal the microcavity.

14. The slot die coater of claim 13, wherein
the slot die coater is further configured to deposit the photo-curable material upon the substrate and to irradiate the deposited photo-curable material so as to form the encapsulation layer.

15. A coating method comprising:
mounting a substrate upon a stage;
applying a photo-curable material to the substrate through a slit nozzle;
irradiating light upon the substrate through an exposure unit positioned to be adjacent to the slit nozzle;
stopping the applying of the photo-curable material; and
after the stopping the applying, stopping the irradiating.

16. The coating method of claim 15, wherein
the exposure unit hardens the photo-curable material while being moved along with the slit nozzle.

17. The coating method of claim 16, wherein:
the slit nozzle and the exposure unit are affixed to the gantry; and
the method further comprises moving the gantry so as to move the slit nozzle together with the exposure unit.

18. The coating method of claim 17, further comprising:
moving the slit nozzle and the exposure unit from one side edge of the substrate toward another side edge of the substrate during the applying and during the irradiating.

19. The coating method of claim 15, wherein the substrate has formed thereon:
a thin film transistor,
a pixel electrode connected to the thin film transistor,
a roof layer formed on the pixel electrode so as to be spaced apart from the pixel electrode while interposing a plurality of microcavities therebetween,
an injection hole exposing a part of each microcavity, and
a liquid crystal layer positioned within the microcavity.

20. The coating method of claim 19, wherein
the irradiating further comprises irradiating light upon the applied photo-curable material so as to harden the photo-curable material, and so as to thereby form an encapsulation layer sealing the microcavity.
